(19) United States
(12) Patent Application Publication
(10) Pub. No.: US 2013/0263775 A1
(43) Pub. Date: Oct. 10, 2013

(54) APPARATUS USED FOR THE GROWTH OF GROUP-III NITRIDE CRYSTALS UTILIZING CARBON FIBER CONTAINING MATERIALS AND GROUP-III NITRIDE GROWN THEREWITH

(71) Applicant: THE REGENTS OF THE UNIVERSITY OF CALIFORNIA, Oakland, CA (US)

(72) Inventors: Siddha Pimputkar, Santa Barbara, CA (US); Paul Von Dollen, Santa Barbara, CA (US); Shuji Nakamura, Santa Barbara, CA (US); James S. Speck, Goleta, CA (US)

(73) Assignee: The Regents of the University of California, Oakland, CA (US)

(21) Appl. No.: 13/860,382

(22) Filed: Apr. 10, 2013

Related U.S. Application Data
(60) Provisional application No. 61/622,232, filed on Apr. 10, 2012.

(51) Int. Cl. C30B 7/10; C30B 9/10

(52) U.S. Cl. CPC C30B 7/10; C30B 7/105; C30B 9/10
USPC 117/71; 117/224; 117/79

(57) ABSTRACT

A method and apparatus for growing crystals in a reactor vessel, wherein the reactor vessel uses carbon fiber containing materials as a structural element to contain the materials for growing the crystals as a solid, liquid or gas within the reactor vessel, such that the reactor vessel can withstand pressures or temperatures necessary for the growth of the crystals. The carbon fiber containing materials encapsulate at least one component of the reactor vessel, wherein stresses from the encapsulated component are transferred to the carbon fiber containing materials. The carbon fiber containing materials may be wrapped around the encapsulated component one or more times sufficient to maintain a desired pressure differential between an exterior and interior of the encapsulated component.

### CROSS REFERENCE TO RELATED APPLICATION

This application claims the benefit under 35 U.S.C. Section 119(e) of U.S. Provisional Patent Application Ser. No. 61/622,232, filed on Apr. 10, 2012, by Siddha Pimputkar, Paul Von Dollen, Shuji Nakamura, and James S. Speck, and entitled “APPARATUS USED FOR THE GROWTH OF GROUP-III NITRIDE CRYSTALS UTILIZING CARBON FIBER CONTAINING MATERIALS AND GROUP-III NITRIDE GROWN THEREWITH,” attorneys' docket number 30794.451-US-P1 (2012-654-1), which application is incorporated by reference herein.

This application is related to the following co-pending and commonly-assigned application:

U.S. Utility patent application Ser. No. 11/921,396, filed on Nov. 30, 2007, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys docket number 30794.129-US-WO (2005-339-2), which application claims the benefit under 35 U.S.C. Section 365(c) of P.C.T. International Patent Application Ser. No. U.S.2005/024239, filed on Jul. 8, 2005, by Kenji Fujito, Tadao Hashimoto and Shuji Nakamura, entitled “METHOD FOR GROWING GROUP-III NITRIDE CRYSTALS IN SUPERCRITICAL AMMONIA USING AN AUTOCLAVE,” attorneys' docket number 30794.129-WO-01 (2005-339-1);

U.S. Utility patent application Ser. No. 12/234,244, filed on Sep. 19, 2008, by Tadao Hashimoto and Shuji Nakamura, entitled “GALLIUM NITRIDE BULK CRYSTALS AND THEIR GROWTH METHOD,” attorneys' docket number 30794.244-US-U1 (2007-809-2), which application claims the benefit under 35 U.S.C. Section 119(e) of U.S. Provisional Patent Application Ser. No. 60/973,662, filed on Sep. 19, 2007, by Tadao Hashimoto and Shuji Nakamura, entitled “GALLIUM NITRIDE BULK CRYSTALS AND THEIR GROWTH METHOD,” attorneys' docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP-III NITRIDE CRYSTALS IN A MIXTURE OF SUPERCRITICAL AMMONIA AND NITROGEN, AND GROUP-III NITRIDE CRYSTALS GROWN THEREBY,” attorneys' docket number 30794.253-US-U1 (2007-774-2), which application claims the benefit under 35 U.S.C. Section 119(e) of U.S. Provisional Patent Application Ser. No. 60/854,567, filed on Oct. 25, 2006, by Tadao Hashimoto, entitled “METHOD FOR GROWING GROUP-III NITRIDE CRYSTALS IN MIXTURE OF SUPERCRITICAL AMMONIA AND NITROGEN AND GROUP-III NITRIDE CRYSTALS,” attorneys' docket number 30794.253-US-P1 (2007-774);

U.S. Utility patent application Ser. No. 13/128,083, filed on May 6, 2011, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorney's docket number 30794.296-US-WO (2009-283-2), which application claims the benefit under 35 U.S.C. Section 365(c) of P.C.T. International patent application Ser. No. PCT/U.S.09/063239, filed on Nov. 4, 2009, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorneys' docket number 30794.296-WO-U1 (2009-283-2), which application claims the benefit under 35 U.S.C. Section 119(e) of U.S. Provisional Patent Application Ser. No. 61/112,560, filed on Nov. 7, 2008, by Siddha Pimputkar, Derrick S. Kamber, James S. Speck and Shuji Nakamura, entitled “REACTOR DESIGNS FOR USE IN AMMONOTHERMAL GROWTH OF GROUP-III NITRIDE CRYSTALS,” attorney's docket number 30794.296-US-P1 (2009-283-1);

U.S. Utility patent application Ser. No. 13/128,088, filed on May 6, 2011, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-WO (2009-284-2), which application claims the benefit under 35 U.S.C. Section 365(c) of P.C.T. International patent application Ser. No. PCT/U.S.09/063238, filed on Nov. 4, 2009, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorneys' docket number 30794.297-WO-U1 (2009-284-2), which application claims the benefit under 35 U.S.C. Section 119(e) of U.S. Provisional Patent Application Ser. No. 61/112,552, filed on Nov. 7, 2008, by Siddha Pimputkar, Derrick S. Kamber, James S. Speck and Shuji Nakamura, entitled “NOVEL VESSEL DESIGNS AND RELATIVE PLACEMENTS OF THE SOURCE MATERIAL AND SEED CRYSTALS WITH RESPECT TO THE VESSEL FOR THE AMMONOTHERMAL GROWTH OF GROUP-III NITRIDE CRYSTALS,” attorney's docket number 30794.297-US-P1 (2009-284-1);

P.C.T. International patent application Ser. No. PCT/U.S.12/04675, filed on Jul. 13, 2012, by Siddha Pimputkar, Shuji Nakamura and James S. Speck, entitled “USE OF GROUP-III NITRIDE CRYSTALS GROWN USING A FLUX METHOD AS SEEDS FOR AMMONOTHERMAL GROWTH OF A GROUP-III NITRIDE CRYSTAL,” attorneys' docket number 30794.419-WO-U1 (2012-020-2), which application claims the benefit under 35 U.S.C. Section 119(e) of U.S. Provisional Patent Application Ser. No. 61/507,170, filed on Jul. 13, 2011, by Siddha Pimputkar and Shuji Nakamura, entitled “USE OF GROUP-III NITRIDE CRYSTALS GROWN USING A FLUX METHOD AS SEEDS FOR AMMONOTHERMAL GROWTH OF A GROUP-III NITRIDE CRYSTAL,” attorneys' docket number 30794.419-US-P1 (2012-020-1), and U.S. Provisional Patent Application Ser. No. 61/507,187, filed on Jul. 13, 2011, by Siddha Pimputkar and James S. Speck, entitled “METHOD OF GROWING A BULK GROUP-III NITRIDE CRYSTAL USING A FLUX BASED METHOD THROUGH PREPARING THE FLUX PRIOR TO BRINGING IT IN CONTACT WITH THE GROWING CRYSTAL,” attorneys' docket number 30794.421-US-P1 (2012-022);

P.C.T. International patent application Ser. No. PCT/U.S.12/04676, filed on Jul. 13, 2012, by Siddha Pimputkar, Shuji Nakamura and James S. Speck, entitled “METHOD FOR IMPROVING THE TRANSPARENCY AND QUALITY OF GROUP-III NITRIDE CRYSTALS AMMONOTHERMALLY GROWN IN A HIGH PURITY GROWTH ENVIRONMENT,” attorneys' docket number 30794.422-WO-U1 (2012-023-2), which application claims the benefit under 35 U.S.C. Section 119(e) of U.S. Provisional Patent Application Ser. No. 61/507,212, filed on Jul. 13, 2011, by Siddha Pimputkar and Shuji Nakamura, entitled “HIGHER PURITY GROWTH ENVIRONMENT FOR THE AMMONOTHERMAL GROWTH OF GROUP-III NITRIDES,” attorneys' docket number 30794.422-US-P1 (2012-023-1); U.S. Provisional Patent Application Ser. No. 61/551,835, filed on Oct. 26, 2011, by Siddha Pimputkar, Shuji Nakamura, and James S. Speck, entitled “USE OF BORON TO IMPROVE THE TRANSPARENCY OF AMMONOTHERMALLY GROWN GROUP-III NITRIDE CRYSTALS,” attorneys' docket number 30794.438-US-P1 (2012-248-1); and U.S. Provisional Patent Application Ser. No. 61/552,276, filed on Oct. 27, 2011, by Siddha Pimputkar, Shuji Nakamura, and James S. Speck, entitled “USE OF SEMIPOLAR SEED CRYSTAL GROWTH SURFACE TO IMPROVE THE QUALITY OF AN AMMONOTHERMALLY GROWN GROUP-III NITRIDE CRYSTAL,” attorneys' docket number 30794.439-US-P1 (2012-249-1);

U.S. Utility patent application Ser. No. 13/744,854, filed on Jan. 18, 2013, by Paul Von Dollen, James S. Speck, and Siddha Pimputkar, entitled “CRYSTAL GROWTH USING NON-THERMAL ATMOSPHERIC PRESSURE PLASMAS,” attorney's docket number 30794.444-US-U1 (2012-456-2), which application claims the benefit under 35 U.S.C. Section 119(e) of U.S. Provisional Patent Application Ser. No. 61/588,028, filed on Jan. 18, 2012, by Paul Von Dollen, James S. Speck, and Siddha Pimputkar, entitled “CRYSTAL GROWTH USING NON-THERMAL ATMOSPHERIC PRESSURE PLASMAS,” attorney's docket number 30794.444-US-P1 (2012-456-1); and

U.S. Utility patent application Ser. No. 13/776,353, filed on Feb. 25, 2013, by Paul von Dollen, and entitled “ELECTROMAGNETIC MIXING FOR NITRIDE CRYSTAL GROWTH,” attorneys' docket number 30794.447-US-U1 (2012-506-2), which application claims the benefit under 35 U.S.C. Section 119(e) of U.S. Provisional Patent Application Ser. No. 61/603,143, filed on Feb. 24, 2012, by Paul von Dollen, and entitled “ELECTROMAGNETIC MIXING FOR NITRIDE CRYSTAL GROWTH,” attorneys' docket number 30794.447-US-P1 (2012-506-1); all of which applications are incorporated by reference herein.

### STATEMENT REGARDING FEDERALLY SPONSORED RESEARCH AND DEVELOPMENT

This invention was made with Government support under Grant No. DMR-0909203 awarded by the National Science Foundation (NSF). The Government has certain rights in this invention.

### BACKGROUND OF THE INVENTION

1. Field of the Invention

This invention relates to an apparatus for the growth of Group-III nitride crystals, wherein the apparatus utilizes carbon fiber containing materials.

2. Description of the Related Art

The terms “(B,Al,Ga,In)N,” or “Group-III nitride,” or “III-nitride,” or “nitride,” as used herein are equivalent and refer to any alloy composition of semiconductors having the formula BₓAl_{y}Ga_{(1-x-y-z)}In_{z}N, where 0<=x<=1, 0<=y<=1, 0<=z<=1, and x+y+z<=1. Moreover, the use of these terms is intended to be broadly construed to include respective nitrides of the single species, In, Al and Ga, as well as binary, ternary and quaternary compositions of such Group-III metal species, including, but not limited to, the compositions of AlN, GaN, AlGaN, InAlN and InAlGaN. Further, materials within the scope of the invention may further include quantities of dopants, or other impurities, or other inclusional materials.

Bulk Group-III nitride crystal growth has been demonstrated using various methods, including the ammonothermal method, and various flux based methods, such as the high nitrogen pressure solution growth and sodium flux method. One characteristic of all these methods is that it appears that all methods produce superior results when operating under both high pressure and high temperature conditions. Therefore, in general, there is a strong motivation to design large reactors that can both withstand high temperature (50° C.-3000° C.) and high pressures (20 atm-40000 atm).

While this task is currently performed using steel based or nickel-chromium (Ni—Cr) based alloys, the parameter space that can be accessed in terms of both high pressure and high temperature is reaching its limits ((<4000 atm and <600° C. for Ni—Cr superalloys) or (<100 atm and <800° C. for steel based reactors)) and further improvements are desired. Additionally, limitations exist with regards to the absolute amount of scaling that can be performed for reactor designs due to size limitations in ingot size that can be produced with high enough quality for the use as autoclaves. Also, absolute limits exist for operational temperatures and pressures due to the creep strength of the metals involved. These limits have been reached in current technologies.

Thus, there is a need in the art for new materials that can be used in such growth methods. The present invention satisfies that need.

### SUMMARY OF THE INVENTION

To overcome the limitations in the prior art described above, and to overcome other limitations that will become apparent upon reading and understanding the present invention, the present invention discloses a method and apparatus for growing crystals, comprising a reactor vessel including at least one volume for containing materials for growing the crystals, wherein the reactor vessel uses carbon fiber containing materials as a structural element to contain the materials as a solid, liquid or gas within the volume, such that the reactor vessel can withstand pressures or temperatures necessary for the growth of the crystals, wherein the pressures range from about 20 atm to about 40,000 atm and the temperatures range from about 50° C. to about 3000° C. The carbon fiber containing material comprises a carbon fiber or a carbon fiber composite, wherein a matrix of the carbon fiber composite may be comprised of carbon, epoxy, polymer, ceramic, metal, glass, organic or inorganic compounds.

The carbon fiber containing materials encapsulate at least one component of the reactor vessel, wherein stresses from the encapsulated component are transferred to the carbon fiber containing materials. Specifically, the carbon fiber containing materials may be wrapped around the encapsulated component one or more times sufficient to maintain a desired pressure differential between an exterior and interior of the encapsulated component. The reactor vessel may include one or more nested volumes and the carbon fiber containing materials are used as a structural element to contain the materials as a solid, liquid or gas within each of the nested volumes.

There also may be one or more layers of additional material that coat the carbon fiber containing material or the encapsulated component, wherein the layers of additional material may comprise interior or exterior liner materials, and are used to: (1) protect the carbon fiber containing material or the encapsulated component, (2) improve on the ability of the carbon fiber containing material or the encapsulated component to maintain a certain pressure or temperature, (3) make the carbon fiber containing material or the encapsulated component chemically resistant to any materials that are placed in contact with the carbon fiber containing material or the encapsulated component, (4) improve on an amount of impurities that are present within the reactor vessel, (5) remove matter from the reactor vessel, or (6) reduce or modify mass loss from the reactor vessel.

### BRIEF DESCRIPTION OF THE DRAWINGS

Referring now to the drawings in which like reference numbers represent corresponding parts throughout:

FIG. 1 is a graph of Strength vs. Temperature for Common Engineering Materials;

FIG. 2 is a graph of Tensile Strength vs. Elastic Modulus showing the comparative strength properties of a single carbon fiber;

FIG. 3 is a schematic of an apparatus according to one embodiment of the present invention; and

FIG. 4 is a flowchart that illustrates a method for growing a compound crystal, such as a Group-III nitride crystal, using the apparatus of FIG. 3.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The growth of Group-III nitride crystals typically requires higher than atmosphere pressure of a nitrogen-containing gas. Traditional chambers used for the growth of these crystals make use of steels or Ni—Cr super alloys. Current applications of these reactor designs have been pushed to the limits in which these materials can operate effectively. To further improve on the growth of Group-III nitride crystals, it is desirable to obtain even higher pressures at elevated operating temperatures. The use of carbon fiber provides a means to further expand the design space in which reactor vessels can be built through the use of ultra high strength materials. Not only is carbon fiber stronger than steel or Ni—Cr, if properly utilized, it can be easily scaled and can operate at temperatures in excess of 2000° C. The present invention results in the production of bulk Group-III nitrides at significantly lower cost, higher throughput, greater growth rate, higher quality, higher purity and transparency.

Apparatus Description

The present invention makes use of carbon fiber based or containing materials, such as carbon fiber composites, in the construction of reactor vessels for compound crystals. Using these materials, it is possible to design large scale reactor vessels that can withstand both the high pressures (20 atm-40000 atm) and high temperatures (50° C.-3000° C.) that are necessary for the growth of Group-III nitride crystals.

This is in part due to the exceptionally high strength of the bonds in the direction of the carbon fiber. Generally speaking, common grade steels have tensile strengths of 500-1000 MPa at temperatures below ˜600° C., and ultra high strength steels have tensile strengths of up to 3500 MPa at room temperatures, while carbon fibers have tensile strengths of ˜6000 MPa at temperatures up to at least 2000° C. Carbon fiber composites actually become stronger as temperatures increase.

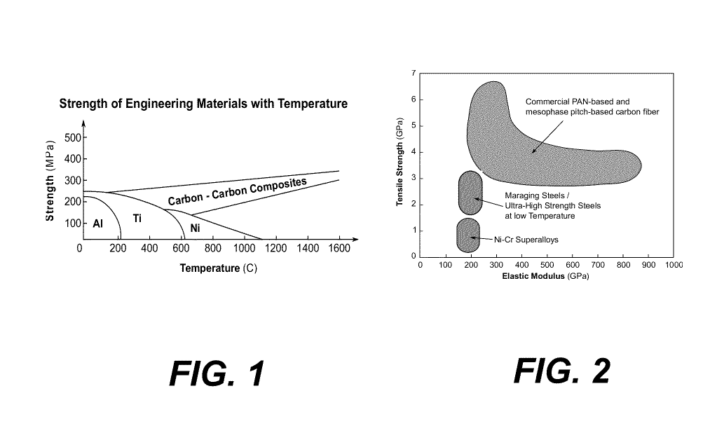

This is reflected in FIG. 1, which is a graph of Strength (MPa) vs. Temperature (C) for common engineering materials including Aluminum (Al), Titanium (Ti), Nickel (Ni) as compared to Carbon-Carbon Composites, and FIG. 2, which is a graph of Tensile Strength (GPa) vs. Elastic Modulus (GPa) showing the comparative strength properties of Ni—Cr superalloys, maraging steels or ultra-high strength steels at low temperature, and commercial polyacrylonitrile (PAN) based and mesophase pitch-based carbon fiber.

While the structural properties of carbon fibers are highly direction, and hence anisotropic, it is possible to arrange the fibers in appropriate weaving patterns to obtain a well engineered product to absorb any applicable stresses along any desired direction. Further engineering also allows one to create material that has a coefficient of thermal expansion that is smaller than that of metals it is encapsulating. This may have considerable impact for high temperature applications, as a significant amount, if not all, of the stresses can be transferred from a metal based alloy to the carbon fiber composite when the carbon fiber based material has been wrapped around the metal based alloy, thereby further extending the pressure and temperature range in which the reactor can safely operate.

The present invention claims the use, however minimal, of any carbon fiber containing material in the design of a reactor vessel for the growth of compound crystals. Carbon fiber containing materials, most notably carbon fiber composites, such as carbon fiber—carbon, carbon fiber—epoxy, carbon fiber—polymer, carbon fiber—ceramic, and carbon fiber—metal composites, are used to contain and generate ultra high pressure volumes within a closed space that are, in turn, used, at least partially and in some part of the process, to generate the compound crystal.

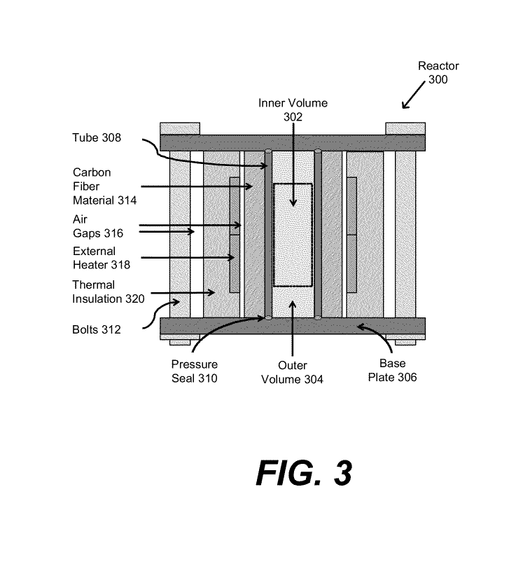

FIG. 3 is a schematic of an apparatus for growing crystals according to one embodiment of the present invention, comprising a reactor vessel including at least one volume for containing materials for growing the crystals, wherein the reactor vessel uses carbon fiber containing materials as a structural element to contain the materials as a solid, liquid or gas within the volume, such that the reactor vessel can withstand pressures or temperatures necessary for the growth of the compound crystals, for example, where the pressures range from about 20 atm to about 40000 atm and the temperatures range from about 50° C. to about 3000° C.

Specifically, the reactor 300 includes one or more nested vessels labeled as inner volume 302 and outer volume 302, either or both of which may be sealed or open. The inner volume 302 may be a tube, cylinder, sleeve or capsule, and is fully contained within the outer volume 304, which also may be a tube, cylinder, sleeve or capsule.

Either or both of the vessels may be considered as crucible for the growth of compound crystals, such as Group-III nitride crystals, which are grown using Group-III containing source materials, Group-III nitride seeds and a nitrogen-containing solvent. Generally, the inner volume 302 and outer volume 304 together are used to perform one or more methods of growing Group-III nitride crystals, wherein the method may comprise a flux based method including a sodium flux based method, a high nitrogen pressure solution growth based method, or an ammonothermal method.

Preferably, either or both of the vessels may operate at the wide pressure and temperature ranges described above. Both or either the inner volume 302 and the outer volume 304 may be comprised of one or more materials that are capable of withstanding ultra-high pressure and temperature, such as metals, ceramics, polymers, carbon fiber such as a carbon fiber based composite, or any combination thereof.

The structure of the outer volume 304 is defined by high strength top and bottom plates 306, a tube 308 of hermetic material, and hermetic high pressure seals 310, wherein the plates 306 are coupled together by ultra high strength bolts 312. A load bearing carbon fiber containing material 314, such as a graphite fiber containing material 314, is positioned on the outer side of the sidewalls of the tube 308, and a first air gap 316 separates the carbon fiber material 314 from external heaters 318. Thermal insulation 320 is positioned on the outer side of the external heaters 318, and a second air gap 316 separates the thermal insulation 320 from the bolts 312.

Specifically, the outer volume 304 is created by sandwiching the tube 308 comprised of the hermetic material, which may be made of a metal, in between the two plates 306, which also may be made of a metal, a ceramic, a carbon fiber containing material, or any combination thereof. Compression along the center line of the tube 308 is achieved by tightening the bolts 312 around the perimeter of the two plates 306. Through engineering, it is possible to provide a hermetic seal 310 between the tube 308 and the two plates 306 at both ends of the tube 308. This, in effect, provides a hermetically sealed outer volume 304 in which any gas, liquid or solid may be placed.

The tube 308 is wrapped on the outside by the carbon fiber containing material 314. As a result, the carbon fiber containing materials 314 encapsulate at least one component of the reactor vessel 300, wherein stresses from the encapsulated component are transferred to the carbon fiber containing materials 314. Moreover, the carbon fiber containing materials 314 may be wrapped around the encapsulated component one or more times sufficient to maintain a desired pressure differential between an exterior and interior of the encapsulated component, e.g., to maintain a pressure differential across the exterior of the tube 308 and the interior of the tube 308. In its most basic form, this invention includes the application of the carbon fiber containing composite materials 314 to contain a solid, liquid, gas, and/or supercritical fluid in the closed space of the outer volume 304 and inner volume 302 at elevated pressures and temperatures.

The carbon fibers in the carbon fiber containing material 314 may be long or short, and continuous or discontinuous. The carbon fibers may be embedded in a matrix. Moreover, the carbon fibers may be weaved or otherwise arranged in such a fashion that a multitude of the strands may run at one or more angles with respect to other strands in order to provide additional strength in carbon fiber containing material 314.

In one example, the carbon fiber containing material 314 comprises a carbon fiber composite, selected from a group comprised of carbon fiber—carbon, carbon fiber—epoxy, carbon fiber—polymer, carbon fiber—ceramic, and carbon fiber—metal composites.

The carbon fiber containing material 314 may be wrapped around another material, such as a carbon fiber containing material, a metal containing material, a ceramic containing material, or any combination thereof.

One or more layers of additional material may coat the carbon fiber containing material 314 or the encapsulated component. For example, it possible that the exterior and/or interior of either or both the inner volume 302 and outer volume 304 may be coated with one or more layers of additional material. Additionally, the tube 308 may be comprised of a single tube, or multiple tubes nested within each other, to tailor towards particular physical or chemical properties.

Specifically, these layers of additional material may comprise interior or exterior liner materials that are used to protect the various components, namely the carbon fiber containing material 314, the exterior of the tube 308, the interior of the outer volume 304, and both the interior and exterior of the inner volume 302. The layers of additional material may be used to: (1) protect the carbon fiber containing material 314 or the encapsulated component, (2) improve on the ability of the carbon fiber containing material 314 or the encapsulated component to maintain a certain pressure or temperature, (3) make the carbon fiber containing material 314 or the encapsulated component chemically resistant to any materials that are placed in contact with the carbon fiber containing material 314 or the encapsulated component, (4) improve on an amount of impurities that are present within the reactor vessel 300 (e.g., preventing contaminates from being incorporated into the inner volume 302 or the outer volume 304), (5) remove matter from the reactor vessel 300 (e.g., removing oxygen from the inner volume 302 or the outer volume 304 using a titanium coating that reacts with oxygen forming titanium dioxide), or (6) reduce hydrogen diffusion out of the inner volume 302 and/or the outer volume 304 by utilizing at least one material with a low permeability of hydrogen under operating conditions. Examples of layers of additional material may include coatings with a noble metal, such as gold, silver, platinum, iridium, palladium, etc., although other materials may also be used, including non-metals, such as ceramics or glasses.

One or more additional elements may be present in the reactor vessel 300, allowing for matter, charged particles, photons, electric fields, or magnetic fields to travel into or out of the reactor vessel 300. For example, the additional elements may comprise electrically conductive wires, optically transparent materials, tubes, or magnetic materials.

After wrapping the tube 308 with the carbon fiber containing material 314, the heaters 318 are then placed outside the carbon fiber containing material 314. These heaters 318 do not need, nor necessarily should, touch the carbon fiber containing material 314 and there can be an air gap 316 between the heaters 318 and the carbon fiber containing material 314. The heaters 318 can then be used to heat the outer volume 304 and inner volume 302, thereby increasing the pressure and creating an environment suitable for the growth of a Group-III nitride crystals, such as GaN.

The external heaters 318 may be present as separate units external to the carbon fiber containing material 314, but may also be incorporated, at least partially or fully, into the carbon fiber containing material 314 itself, or use the carbon fiber containing material 314 itself as the heater. This combination would allow the carbon fiber containing material 314 to additionally act as a heating source, thereby eliminating the need for a separate heater 318. Moreover, the carbon fiber containing material 314 maybe used as a heat sink as well as a heat source.

As the outer volume 304 is hermetically sealed, it is possible to achieve appreciable pressures at appreciable temperatures as the ultra high strength bolts 312 can safely retain the force exerted by the pressure on the two plates 306 capping the tube 308. Given that one can place thermal insulation materials 320 between the heaters 318 and the bolts 312, the temperature of the bolts 312 can be very low, well below temperatures under which the bolts 312 will lose any appreciable strength leading to creep. The hoop stresses can be transferred from the tube 308 to the overwrapped carbon fiber containing materials 314. Given the stiffness and strength of the carbon fiber containing material 314, the fibers will provide the necessary strength to prevent any expansion of the tube 308 and prevent creeping and ultimate failure of the tube 308. As carbon fibers do not lose strength at increased temperatures (quite the contrary, they become stronger as temperature increases), the carbon fiber containing material 314 will not creep and hence cause catastrophic failure and rupture of the tube 308.

Although this embodiment described herein uses multiple nested vessels, namely inner volume 302 and outer volume 304, wherein the inner volume 302 is completely surrounded by or nested within the larger sized outer volume 304, other embodiment may use more than two nested vessels or only a single vessel. Also, while the embodiment described herein only describes the use of one structure of carbon fiber based material 314 to retain significant stresses generated by elevated pressures, multiple such structures may be used as well, for example, each of the volumes 302, 304 may use such a carbon fiber containing material 314.

Note that this example, which should not been seen to be limiting in any way, is provided to demonstrate one possible application of this invention towards the ammonothermal growth of GaN.

One alternative embodiment, as applied to the sodium flux method, would include a larger outer vessel which is designed using carbon fiber containing materials to retain significant pressures. Within this large outer vessel, one places insulation material, heaters and a smaller inner vessel which is also designed using carbon fiber containing materials to retain significant pressures. The insulation material can be used to isolate the heaters from the carbon fiber based elements of the larger outer vessel to ensure that a certain critical temperatures are not exceeded. The heaters, in turn, are designed to heat the smaller inner vessel. A Group-III nitride crystal is then grown within the smaller inner vessel, wherein the smaller inner vessel may or may not be at the same pressure as the pressure retained by the larger outer vessel. The benefits of this design allows one: (i) to obtain an absolute pressure within the smaller inner vessel at significantly higher pressures than would be possible if only the larger outer vessel were used and (ii) to decouple the pressure containing materials from the temperature exposed materials.

One motivation to use internal heating and using methods to reduce the experienced temperature at the carbon fiber containing material is that carbon fiber composite may be used that are preferable for lower temperature applications. One such composite includes the use of carbon fiber—polymer matrix (for example, a carbon fiber—epoxy composite) which is currently used for hydrogen storage tanks at room temperature.

While it is possible to make use of internal heating as described in the previous paragraphs, this is not necessary, as one of the strengths of carbon fiber containing materials is that they retain their strength at extreme temperatures. This leads to the possibility of externally heating the carbon fiber encapsulated volume and arranging any number of elements within the chamber to one's desires to achieve the best possible growth of Group-III nitride crystals. The suitable environment for growth may include an ammonia, nitrogen, and hydrogen-containing environment. One or more vessel or containers may exist within the carbon fiber encapsulated volume to hold a liquid, such as molten metals.

Process Description

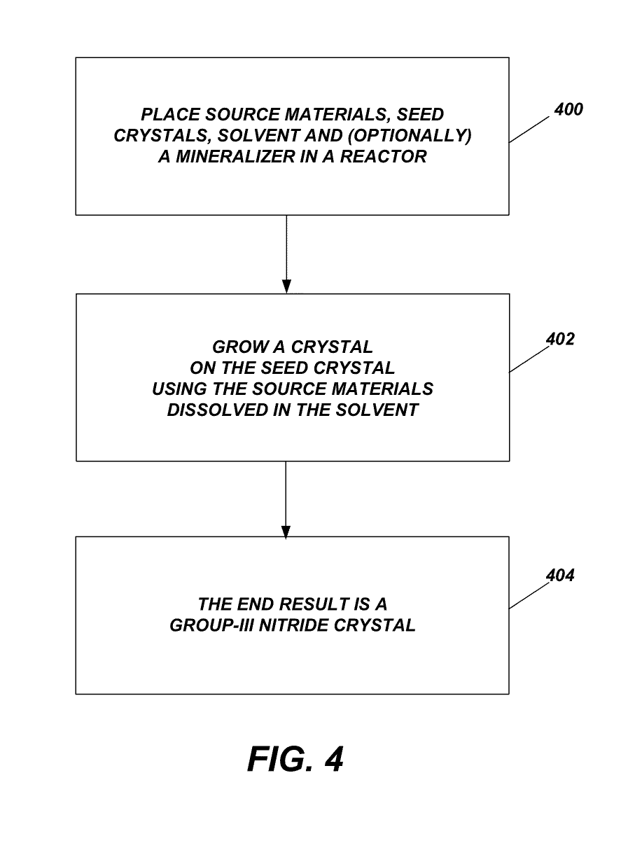

FIG. 4 is a flowchart that illustrates a method for growing a compound crystal, such as a Group-III nitride crystal, using the apparatus of FIG. 3, according to one embodiment of the present invention.

Block 400 represents placing one or more Group-III nitride seed crystals, one or more Group-III containing source materials, and a nitrogen-containing solvent in the reactor 300, wherein the seed crystals may be placed in the inner volume 302, the source materials may be placed in the outer volume 304, and the nitrogen-containing solvent is transported between the outer volume 304 and the inner volume 302. (Alternatively, the seed crystals may be placed in the outer volume 304, and the source materials may be placed in the inner volume 302, and the nitrogen-containing solvent may be transported between the inner volume 302 and the outer volume 304.) In one embodiment, the seed crystals comprise a Group-III containing crystal; the source materials comprise a Group-III containing compound, a Group-III element in its pure elemental form, or a mixture thereof, i.e., a Group-III nitride monocrystal, a Group-III nitride polycrystal, a Group-III nitride powder, Group-III nitride granules, or other Group-III containing compound; and the nitrogen-containing solvent is supercritical ammonia or one or more of its derivatives. Moreover, additional materials or elements may be present within the reactor vessel 300.

Block 402 represents growing Group-III nitride crystals on one or more surfaces of the seed crystals using the source materials dissolved in the solvent, wherein the conditions for growth include forming a temperature gradient between the seed crystals and the source materials that causes a higher solubility of the source materials in the solvent in one zone (either the inner volume 302 or the outer volume 304) and a lower solubility, as compared to the higher solubility, of the source materials in the solvent in another zone (either the outer volume 304 or the inner volume 302). Specifically, growing the Group-III nitride crystals on one or more surfaces of the seed crystal occurs by creating a temperature gradient in the solvent between the inner volume 302 and the outer volume 304 that produces a differential in the solubility of the source materials in the solvent. For example, the temperature gradient may range between 0° C. and 1000° C.

Block 404 comprises the resulting product created by the process, namely, one or more Group-III nitride crystals grown on the seed crystals. The Group-III nitride crystals are characterized as AlₓB_{y}Ga_{z}In_{(1-x-y-z)}N, where 0<=x<=1, 0<=y<=1, 0<=z<=1, and x+y+z<=1. For example, the Group-III nitride crystals may be AlN, GaN, InN, AlGaN, AlInN, InGaN, etc. A Group-III nitride substrate may be created from a Group-III nitride crystal, and a device may be created using the Group-III nitride substrate.

### REFERENCES

The following references are incorporated by reference herein:

[1] U.S. Patent Application Publication No. 2003/0140845, filed Jan. 31, 2002, published Jul. 31, 2003, by D'Evelyn et al., and entitled “PRESSURE VESSEL.”

[2] U.S. Patent Application Publication No. 2009/0301387, filed Jun. 5, 2008, published Dec. 10, 2009, by D'Evelyn, and entitled “HIGH PRESSURE APPARATUS AND METHOD FOR NITRIDE CRYSTAL GROWTH.”

[3] U.S. Patent Application Publication No. 2011/0183498, filed Jan. 25, 2011, published Jul. 28, 2011, by D'Evelyn, and entitled “HIGH PRESSURE APPARATUS AND METHOD FOR NITRIDE CRYSTAL GROWTH.”

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. An apparatus for growing crystals, comprising:
(a) a reactor vessel including at least one volume for containing materials for growing the crystals;
(b) wherein the reactor vessel uses carbon fiber containing materials as a structural element to contain the materials for growing the crystals at pressures or temperatures necessary for the growth of the crystals.

2. The apparatus of claim 1, wherein the carbon fiber containing materials comprise a carbon fiber or a carbon fiber composite, wherein the matrix of the composite may be comprised of carbon, epoxy, polymer, ceramic, metal, glass, organic or inorganic compounds.

3. The apparatus of claim 1, wherein the pressures range from about 20 atm to about 40000 atm and the temperatures range from about 50° C. to about 3000° C.

4. The apparatus of claim 1, wherein the carbon fiber containing materials encapsulate at least one component of the reactor vessel.

5. The apparatus of claim 4, wherein stresses from the encapsulated component are transferred to the carbon fiber containing materials.

6. The apparatus of claim 4, wherein the carbon fiber containing materials are wrapped around the encapsulated component one or more times sufficient to maintain a desired pressure differential between an exterior and interior of the encapsulated component.

7. The apparatus of claim 1, wherein the reactor vessel includes one or more nested volumes and the carbon fiber containing materials are used as a structural element to contain the materials for growing the crystals as a solid, liquid, plasma, supercritical fluid, or gas within at least one of the nested volumes.

8. The apparatus of claim 1, further comprising one or more layers of additional material that coat the carbon fiber containing materials or the encapsulated component, wherein the layers of additional material comprise interior or exterior materials, and are used to:
(1) protect the carbon fiber containing materials or the encapsulated component,
(2) improve on the ability of the carbon fiber containing materials or the encapsulated component to maintain a certain pressure or temperature,
(3) make the carbon fiber containing materials or the encapsulated component chemically resistant to any materials that are placed in contact with the carbon fiber containing materials or the encapsulated component,
(4) improve on an amount of impurities that are present within the reactor vessel,
(5) remove matter from the reactor vessel, or
(6) reduce or modify mass loss from the reactor vessel.

9. The apparatus of claim 1, wherein the carbon fiber containing material is used as a heat source or sink.

10. The apparatus of claim 1, wherein one or more additional elements are present in the reactor vessel allowing for matter, charged particles, photons, electric fields, or magnetic fields to travel into or out of the reactor vessel.

11. The apparatus of claim 10, wherein the one or more additional elements comprise electrically conductive wires, optically transparent materials, tubes, or magnetic materials.

12. The apparatus of claim 1, wherein the materials for growing the crystals comprise Group-III containing source materials, Group-III nitride seeds and a nitrogen-containing solvent, and the crystals comprise Group-III nitride crystals.

13. A method for growing crystals, comprising:
(a) growing the crystals in a reactor vessel including at least one volume for containing materials for growing the crystals;
(b) wherein the reactor vessel uses carbon fiber containing materials as a structural element to contain the materials for growing the crystals at pressures or temperatures necessary for the growth of the crystals.

14. The method of claim 13, wherein the carbon fiber containing materials comprise a carbon fiber or a carbon fiber composite, wherein the matrix of the composite may be comprised of carbon, epoxy, polymer, ceramic, metal, glass, organic or inorganic compounds.

15. The method of claim 13, wherein the pressures range from about 20 atm to about 40000 atm and the temperatures range from about 50° C. to about 3000° C.

16. The method of claim 13, wherein the carbon fiber containing materials encapsulate at least one component of the reactor vessel.

17. The method of claim 16, wherein stresses from the encapsulated component are transferred to the carbon fiber containing materials.

18. The method of claim 16, wherein the carbon fiber containing materials are wrapped around the encapsulated component one or more times sufficient to maintain a desired pressure differential between an exterior and interior of the encapsulated component.

19. The method of claim 13, wherein the reactor vessel includes one or more nested volumes and the carbon fiber containing materials are used as a structural element to contain the materials for growing the crystals as a solid, liquid, plasma, supercritical fluid, or gas within at least one of the nested volumes.

20. The method of claim 13, further comprising one or more layers of additional material that coat the carbon fiber containing materials or the encapsulated component, wherein the layers of additional material comprise interior or exterior materials, and are used to:
(1) protect the carbon fiber containing materials or the encapsulated component,
(2) improve on the ability of the carbon fiber containing materials or the encapsulated component to maintain a certain pressure or temperature,
(3) make the carbon fiber containing materials or the encapsulated component chemically resistant to any materials that are placed in contact with the carbon fiber containing materials or the encapsulated component,
(4) improve on an amount of impurities that are present within the reactor vessel,
(5) remove matter from the reactor vessel, or
(6) reduce or modify mass loss from the reactor vessel.

21. The method of claim 13, wherein the carbon fiber containing material is used as a heat source or sink.

22. The method of claim 13, wherein one or more additional elements are present in the reactor vessel allowing for matter, charged particles, photons, electric fields, or magnetic fields to travel into or out of the reactor vessel.

23. The method of claim 22, wherein the one or more additional elements comprise electrically conductive wires, optically transparent materials, tubes, or magnetic materials.

24. The method of claim 13, wherein the materials for growing the crystals comprise Group-III containing source materials, Group-III nitride seeds and a nitrogen-containing solvent, and the crystals comprise Group-III nitride crystals.
